(19) United States
(12) Patent Application Publication
(10) Pub. No.: US 2024/0205100 A1
(43) Pub. Date: Jun. 20, 2024

(54) AUTOMATED ANOMALY DETECTION MODEL QUALITY ASSURANCE AND DEPLOYMENT FOR WIRELESS NETWORK FAILURE DETECTION

(71) Applicant: HEWLETT PACKARD ENTERPRISE DEVELOPMENT LP, SPRING, TX (US)

(72) Inventors: LAURA RICHTER, Cape town (ZA); Leonard Botha, Cape Town (ZA); Derwin Thulani Ngomane, Cape Town (ZA); Stephen Hulme, Cape Town (ZA); Njabulo Ndlovu, Cape Town (ZA)

(21) Appl. No.: 18/085,380

(22) Filed: Dec. 20, 2022

(51) Int. Cl. H04L 41/147; H04L 41/06; H04L 41/08; H04L 41/14; H04L 41/40; H04L 43/16

(52) U.S. Cl. CPC H04L 41/147; H04L 41/06; H04L 41/0886; H04L 41/145; H04L 41/40; H04L 43/16

(57) ABSTRACT

Systems and methods are provided for automated anomaly detection model quality assurance (QA) and deployment for wireless network failure prediction. Network failure prediction can leverage models trained to detect issues on a network and predict failure scenarios by identifying anomalous issues indicative of failure conditions. To keep these models up to date with changes in network behavior and configurations, the models are recalibrated from time to time. Implementations disclosed herein provide for automated evaluation and deployment of recalibrated models, while assuring issue detection results from the recalibrated models accurately reflect current network conditions. To do this, implementations disclosed herein determine QA metrics for recalibrated, candidate models, QA thresholds from previously deployed models, and QA criteria from a currently deployed model. Based on a comparison of the QA metrics with the QA thresholds and the QA criteria, implementations disclosed herein automatically deploy recalibrated, candidate models without human or external intervention.

### BACKGROUND

With the advent of fifth generation (5G) networks, physical network functions and equipment have evolved into virtualized network functions (VNFs) and containerized NFs (CNFs). As a result, network complexity has increased exponentially, and the number of elements and aspects of a network that need to be operationalized and managed has also increased, along with the amount of data produced by each NF. Current 5G VNFs/CNFs generate raw data (from 5G RAN/CORE entities) in the form of counters and network and/or service performance metrics. Such counters and metrics can be identified by trained machine-learning models.

### BRIEF DESCRIPTION OF THE DRAWINGS

The present disclosure, in accordance with one or more various implementations, is described in detail with reference to the following figures. The figures are provided for purposes of illustration only and merely depict typical or example implementations.

FIG. 1 illustrates an example service provider workflow in accordance with implementations of the disclosed technology.

FIG. 2 illustrates an example service provider system architecture in accordance with implementations of the disclosed technology.

FIG. 3 illustrates an example anomaly detection system in accordance with implementations of the disclosed technology.

FIG. 4 illustrates an example graphical representation of a model plot generated by an anomaly detection model according to an example implementation of the present disclosure.

FIG. 5 is a schematic representation of an example architecture for a model quality assurance phase in accordance with implementations of the present disclosure.

FIGS. 6A and 6B illustrate example performance distributions that can be used to generate quality assurance thresholds in accordance with implementations of the present disclosure.

FIG. 7 illustrates an example sensor communicating with an anomaly detection system in accordance with some implementations of the present disclosure.

FIGS. 8A and 8B are example visualizations generated by a GUI for selecting an a model for automatic deployment according to implementations of the disclosed technology

FIG. 9 is an example computing component that may be used to implement various features of automated model quality assurance and deployment in accordance with the implementations disclosed herein.

FIG. 10 is another example computing component that may be used to implement various features of automated model quality assurance and deployment in accordance with the implementations disclosed herein.

FIG. 11 is an example computer system that may be used to implement various features of automated model quality assurance and deployment of the present disclosure.

The figures are not exhaustive and do not limit the present disclosure to the precise form disclosed.

### DETAILED DESCRIPTION

Service fulfillment and service assurance can be implemented to ensure operation of a Service Provider (SP). Part of the service assurance aspect of a SP's operation can involve addressing failures, such as network function (NF) failures, that can lead to service outages and/or service degradations in carrier scale telecommunication networks. Such failures result in unacceptable business outcomes for a SP. Therefore, SPs have increasingly begun looking for proactive approaches to addressing NF failures. The urgency for proactive carrier-grade solutions is further heightened due to the deployment of the latest network technologies, e.g., 5G, which have resulted in increased complexities involved in troubleshooting and remediating network issues (although various implementations disclosed herein are not limited to any particular network or system or network technology).

Network function virtualization (NFV) is an emerging design approach for migrating physical, proprietary, hardware boxes offering network services to software running in virtual machines or containers on industry standard physical servers, particularly in the telecommunications industry. The classical approach to network architecture is based upon fragmented, purpose-built hardware for implementing NFs—also known as physical NFs (e.g., firewalls, deep packet inspectors, network address translators, routers, switches, radio base station transceivers) which require physical installation at every site where they are needed. In contrast, NFV aims to consolidate many network equipment types onto, for example, standardized high volume servers, switches, and storage through the implementation of virtual network functions (VNFs) in software which can run on a range of standard hardware. Furthermore, NFV aims to transform network operations because the VNFs can be dynamically moved to, or instantiated in, various locations in the network as required without the need for installation of new hardware. Furthermore, multiple physical NFs and VNFs can be configured together to form a “service-chain” and packets steered through each network function in the chain in turn.

With the advent of containerization and CNFs (Container Network Functions), dynamicity from edge to core in, e.g., 5G, has become possible, implying a dynamic and software/data-driven approach for network operations may be adopted. As will be described herein, a transition to more proactive management of NFs can be effectuated through the exploitation of large amounts of data generated by these networks.

Accordingly, various implementations of the present disclosure are directed to systems and methods for detecting failures, and notifying a SP in advance of the detected failures in real time. In particular, implementations disclosed herein provide for systems that can detect issues on the network and identify anomalous issues that can lead to service outages, and which can be detected and/or identified in advance of the service outages actually occurring. For example, machine-learning models can be generated that are trained to detect these issues and identify those that are anomalous. Then, machine learning models can be operationalized in a real-time production engines so that early warning signals of a potential service outage (or degradation) can be provided. In this way, a SP's operations' teams and/or systems (e.g., assurance systems) can take proactive remediation steps or assurance actions to avert such service outages, failures, or other associated problems.

Various implementations can be based, e.g., on the following heuristic observations. NFs, whether physical, virtualized or containerized, may generate, e.g., tens of thousands of events or log messages (which may be collectively referred to herein as issues) in the time frame preceding and leading up to a service degradation or outage situation. The number of distinct types of events or log messages from a system/network are finite in number and most often do not exceed a couple of hundred message types making learning/analyzing such events/logs feasible, although various implementations are not necessarily limited by any number of distinct message types. Further still, most failure scenarios involving NFs demonstrate a distinctive histogram of counts and sequence of message types. The histogram of message type counts tend to exhibit a good fit to an exponential or power law function. Moreover, an associated, fitted, continuous probability density function (PDF) should make for a good fit to, for example, the Exponential, Gamma, Weibull or Pareto distribution functions, or other mathematical criterion that positively qualifies a failure scenario as a good candidate for identifying when to send an early warning signal.

For example, in a 5G context, Radio Units (RUs) in a 5G Radio Access Network (RAN) can become completely non-operational or partially degraded as a consequence of any one or more of the following issues: radio transmission and reception problems; environmental issues like high temperatures in the operating environment; poor power conditions and associated rectifier malfunctions; failing or weakening batteries; degraded/slowly degrading wireless backhaul IP connections; poor weather conditions leading to problems in line-of-sight microwave links; etc. Such issues are indicative of events generated automatically by a 5G network, and can be used as input to the disclosed systems/methods which can learn how to detect their occurrence and evaluate whether certain issues are anomalous from normal operation. It should be understood that 2G, 3G, and 4G networks can experience the same/similar issues, and thus, various implementations can be applied in those contexts as well. Similarly, data units (DUs) as well as control units (CUs) can suffer from similar problems leading to operational degradation and/or failures. It should be further understood that various implementations are applicable to wireline networks and other types of automatically generated events.

The systems and methods disclosed herein for predicting service degradation and outages based on NF failures and for generating early warnings involve a “discovery” phase, an “operationalization” phase, and a “production run-time” phase.

In the discovery phase, statistical techniques quantitatively qualify and identify one or more issues (e.g., events and/or log messages) that can be an indicator for possible future failure predictions. Time series issue data is received, type-categorized, and labeled. Anomalous issue candidates are identified. Scoring can be performed on the candidates, and ultimately, the time between occurrence of issues having the highest scores computed and used to estimate time frames for early warning for anomalous issues. The data-fitting process can be accomplished using, e.g., least squares regression (LSR), Simulated Annealing, and Chi-squared/Kolmogorov-Smirnov tests on a big data computational framework (Spark or Flink or other framework supporting stateful computations over high volume and throughput data streams).

In the operationalization phase, the identified predictive failure scenarios are deployed as production run-time machines. Machine learning can refer to methods that, through the use of algorithms, are able to automatically turn data sets (such as training data sets) into information models. In turn, those models can be used for making predictions based on patterns or inferences gleaned from other data (such as testing data sets or real world data sets). There has been a push to implement machine learning in enterprise environments, e.g., businesses, so that these entities may leverage machine learning to provide better services and products to their customers, become more efficient in their operations, etc. Implementing machine learning into the enterprise context, also referred to as operationalization, can involve the deployment (and management) of trained models, i.e., putting trained models into production.

In the production run-time phase, the production run-time machines will analyze a real-time incoming stream of data from the NFs, detect issues from the stream of data, identify anomalous issues that are indicators of failure scenarios, and generate early warning signals with an associated probability and estimated time frame in which the degradation or outage scenario will occur. For example, product run-time machine detect issues and identify anomalous issues using an anomaly detection engine. The anomaly detection engine uses trained models to identify whether or not a detected issue rises to the level of an anomaly. The design of the production run-time inference machine may involve neural networks (NNs), such as Word-To-Vector NN, a Convolutional NN (CNN), a Long Short Term Memory (LSTM) NN, and the like running back-to-back. It should be understood that other artificial intelligence/machine learning methods/mechanisms can be leveraged in accordance with other implementations.

As SP operations scale up and customer numbers increase, the amount of work involved in maintaining the models over time increases accordingly. Production run-time models tend to deteriorate over time due to shifts in trends and/or patterns due to changes in network behavior and/or network configurations. Quality assurance can be implemented through model maintenance to keep the quality and evaluation accuracy of production run-time models within acceptable limits when refreshed and applied to new data. For example, models can be periodically retrained on new training data sets (e.g., training data updated to reflect most recent network behavior and/or configurations) and then redeployed to production run-time machines.

Conventional approaches to model maintenance generally involve an operator manually monitoring, testing, and validating model quality to detect any degradation, which can become a highly time- and labor-intensive process. Furthermore, an SP may service hundreds of customers, each of which may utilize different models for detecting numerous different failure scenarios. As a result, quality assurance through model maintenance can become prohibitive as the number of customized models increases exponentially, and it may not be feasible to retrain and redeploy increasing number of models according to the conventional approaches.

The implementations of the present disclosure provide for systems and methods for quality assurance through automated model maintenance and deployment onto production run-time machines. Implementations disclosed herein generate new, candidate models for deployment in an anomaly detection engine by retraining models on historical training data sets that reflect recent network configurations and/or behavior. For each candidate model, testing data is applied to the candidate model, which generates output data in the form of issue detection results. For example, the candidate model detects issues from the testing data and sets anomaly thresholds for detecting anomalous issues. From issue detection results, implementations disclosed herein, determine a plurality of quality assurance (QA) metrics for the candidate model. For example, two QA metrics can be calculated: a model value in the form of a central value the issue detection results (e.g., a mean or median of the output data) and a range of scale of the output data (also referred to as a width) associated with the candidate model. The range of the scale may be the anomaly threshold from which a respective candidate model determines that an issue is an anomalous issue. The scale may be determined as standard deviations of differences between the data and the residuals of the model. In another example, the scale may be determined as a median absolute deviation, while in another example the scale may be determined using a statistical Gaussian scale estimator referred to as Qn. The range of the scale may be based on applying a factor (e.g., an integer multiplier) to the scale. The factor may be, for example, a multiplier that is applied to the scale to calculate the range of the scale, such as a numerical integer. In an example case, the factor may be five and the range of the scale may be five standard deviations from the model value of the respective candidate model.

Implementations disclosed herein also retrieve a currently deployed model (also referred to as an active model) and a plurality of previously deployed models corresponding to the candidate model. The plurality of previously deployed models may include a number of models that were deployed within a set time period (e.g., 1 month, 2 months, etc.), which can include the active model. The testing data set is also applied to the active model and each of the previously deployed models to generate respective output data in the form of issue detection results from which respective network failure scenarios can be predicted (e.g., prediction results).

From the output data of the previously deployed models, a plurality of QA thresholds can be derived for determining whether or not a candidate model can be automatically deployed or flagged for review of an SP operator. For example, the plurality of QA thresholds may be based on performance distributions derived from the output data of the previously deployed model collectively. For example, a first QA threshold may be based on a first performance distribution derived from model values indicative of a central value of issue detection results included as part of network failure prediction results, each of which is associated with a previously deployed models. A second QA threshold may be based on a second performance distribution derived from ranges of the scales of the issue detection results, each of which is associated with a previously deployed models. The first threshold may set as a model value corresponding to a first percentile (e.g., 90th percentile, 99th percentile, etc.) of the first performance distribution and the second threshold set as a range of the scale corresponding to a second percentile (e.g., 90th percentile, 99th percentile, etc.) of the second performance distribution. Further, from the output data of the active model, a criteria can be derived that is also used to determine whether or not a candidate model can be automatically deployed or flagged review. For example, the criteria may comprise a model value and a range of the scaleof the issue detection results associated with the currently deployed model.

The disclosed technology compares the QA metrics of a candidate model to the plurality of QA thresholds and the QA criteria to determine whether or not to deploy the candidate model. For example, the candidate model can be automatically deployed if the QA metrics satisfy each of the plurality of QA thresholds and the QA criteria. That is, for example, if the model value of the candidate model is less than the first threshold (e.g., is less than the model value of the first percentile of the first performance distribution), the range of the scale of the candidate model is less than the second threshold (e.g., is less than range of the scale of the second percentile of the second performance distribution), and the range of the scale of the candidate model overlaps with the QA criteria (e.g., range of the scale of the current model) based on the model values, the candidate model can be automatically deployed. Otherwise, if any one of the plurality of QA thresholds or the QA criteria are not satisfied, the candidate models can be flagged and an alert generated for review of the candidate model against the active model. The SP operator may choose to deploy or not deploy the candidate model based on review via a graphical user interface (GUI).

It should be noted that although various implementations are described in the context of NF instances and NF failures, implementations are not necessarily limited to NFs. That is, any system or network application or aspect(s) that can be used as a basis for predicting some failure or outage can be leveraged. Moreover, detected events or issues need not be limited to system failures. That is, a system can be monitored with respect to messages, events, or other status indicators of a particular aspect(s) of the system that a SP (or other entity) wishes to track.

It should be noted that the terms “optimize,” “optimal” and the like as used herein can be used to mean making or achieving performance as effective or perfect as possible. However, as one of ordinary skill in the art reading this document will recognize, perfection cannot always be achieved. Accordingly, these terms can also encompass making or achieving performance as good or effective as possible or practical under the given circumstances, or making or achieving performance better than that which can be achieved with other settings or parameters.

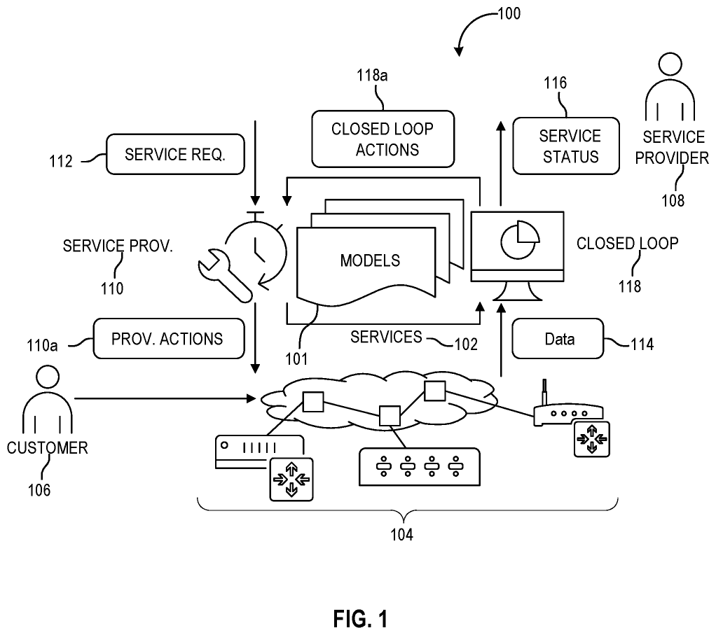

FIG. 1 illustrates an example Service Provider (SP) workflow 100 that is representative of actions, operations, events, etc. that may occur in the context of service fulfillment and service assurance. The term “service” as utilized herein, can refer to the orchestration of changes in a (often complex) system of interactive services, networks, and systems for the creation of communication services or products. For example, a service can be an entity, class, node, vertex, etc. Accordingly, in a traditional sense for example, a service can be some collection of actions effectuated through one or more computational/memory resources (physical and/or virtual) that produce a desired result, but underlying that collection of actions are parameters, relationships, and/or potential actions impacting or involving one or more of the actions making up the collection of actions.

As illustrated in FIG. 1, services 102, e.g., a 5G service, may involve certain physical, virtual and/or containerized resources implemented on infrastructure 104, such as servers, wireless local area network (WLAN) devices, e.g., access points, routers, etc. Following the 5G service example, it should be understood that resources, like services, described above, can be, but are not limited to components, aspects, objects, applications, or other elements that provide or act as a prerequisite to such element, e.g., another resource or service. For example, infrastructure 104 can include connections to/from one or more physical and/or virtual infrastructure, which can also be resources. In some implementations, a resource can refer to a first service that is in an active state before another service is designed or utilized to effectuate the first service. Furthermore, in some implementations, services and resources can be hierarchical and nested. Such services 102 can be provided to a customer 106 by a service provider 108 upon being provisioned through a service provisioning mechanism/process 110 and corresponding provisioning actions 110a in response to service requests 112 from, e.g., a customer relation management (CRM) layer. In particular, services may be defined (e.g., a service's appearance and/or how a service is built) in a catalog that may also reflect relationships between services (parent-child and/or linked relationships, inheritance relationships, etc.). It should be understood that services and services' structure can be maintained in a service inventory. Service requests 112 may include service data collection, service order validation, service order orchestration, service order tracking and/or management, and the like. Based on the building blocks that define a service, the service resources may be activated. Accordingly, the services 102 may be specified as models 101.

As alluded to above, and following the example 5G service, a 5G service may be deployed on multiple premises using a combination of physical hardware (e.g., servers, antennas, cables, WAN terminations), Virtual Network Functions (VNFs) and Containerized Network Functions (CNFs). Such services may be used for intercepting various types of mobile traffic generated by client devices in the premises, and/or directing specific traffic to applications hosted by the enterprise. Such services may also be part of an end-to-end service, providing functionalities such as data-reduction, analytics, remote monitoring and location-aware services used by the customers and employees. Another service example may be a classical cloud-like service offering, but combined with network service offerings, such as different security zones (customer, employee, legal, etc.) combined with firewalling, routing configurations, and extensions to end-customer premises.

Any issues or problems that exist or may arise regarding any service(s) may be identified through the collection of observability data, such as but not limited to, metrics and counters, events, and probe data 114 (referred to herein as issues) from the physical hardware, virtual resources, and/or containerized resources implemented on infrastructure 104. According to implementations disclosed herein, the physical hardware, virtual resources, and/or containerized resources used to collect observability data may be referred to as sensors. A service impact analysis may be performed to determine a service's status 116, and service provider 108 may be informed of any such issues/problems. Resolution of such service issues/problems can be automated via closed loop remediation processing 118 that are realized with closed loop remediation actions 118a, and healing or remediation processes may be triggered.

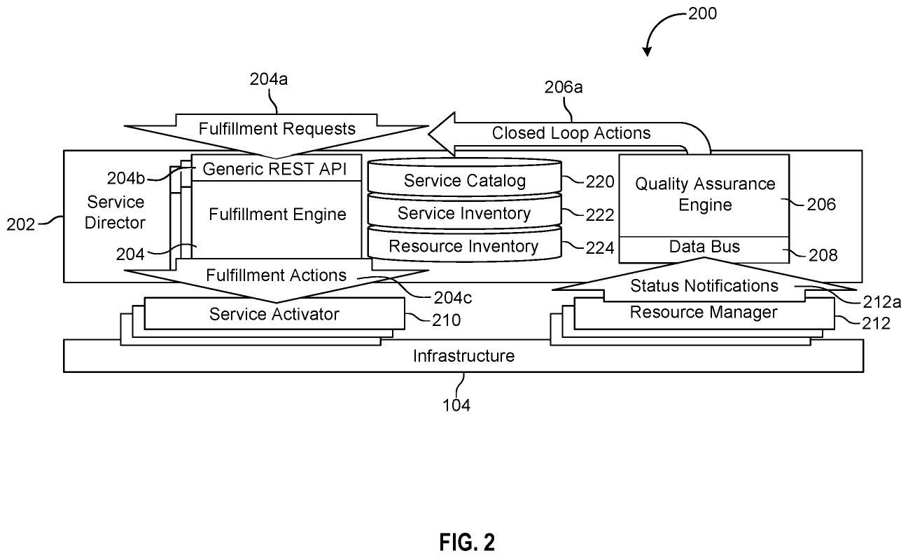

FIG. 2 is a schematic representation of a SP system architecture 200 that includes service fulfillment and service assurance functionality. A service director 202 may refer to a model-based orchestration engine for managed hybrid services. Service director 202 may, in some implementations, comprise a service fulfillment engine 204 and a service assurance engine 206. In accordance with various implementations, a closed loop framework or mechanism for addressing both service fulfillment and assurance can be realized, although a closed loop framework is not necessary. That is, and as alluded to above, service-level issues, problems, etc. can be addressed automatically by service fulfillment actions. In other words, the same mechanism (service fulfillment engine 204) used to provision/fulfill service requests can be used to solve service incidents identified by, and as instructed by service assurance engine 206. Moreover, as can be appreciated from FIG. 2, that a single service inventory 222 is implemented (as well as a single service catalog 220 and a single resource inventory 224) between service fulfillment engine 204 and service assurance engine 206.

For example, fulfillment (service) requests 204a may be received by service director 202 via a RESTFUL application programming interface (API) 204b. Service fulfillment engine 204 may perform various fulfillment (service provisioning) actions. In particular, service fulfillment engine 204 may define services through mathematical models and store these service definitions in a service catalog 220, which may be a database, database partition, or other data repository. Moreover, service fulfillment engine 204 may orchestrate service instantiation based on defined rules and policies. As a result of such service instantiation by service fulfillment engine 204, a service inventory 222 can be automatically populated. It should be understood that service inventory 222, like service catalog 220, may be a database, database partition, or other data repository. Service inventory 222 can contain versions products, services, and/or resources as defined in the service catalog 220, while a resource inventory 224 may contain information regarding resources (e.g., elements of infrastructure 104) that can be leveraged to provide services. A service activator 210 may implement or carry out execution of the fulfillment actions 204c (i.e., executing commands regarding service provisioning) on the requisite resources comprising infrastructure 104.

Once a service(s) is instantiated and operational for a SP, from the service assurance perspective, a resource manager 212 may perform, e.g., resource monitoring on the sensors (e.g., physically and/or virtually-implemented resources) and status notifications 212a (e.g., counters and metrics) can be collected and distributed to an enterprise service bus, data bus, or similar integration system. In this implementation, a data bus 208 may be used, such as Apache Kafka®, an open-source stream-processing software platform, generally leveraged for handling real-time data feeds. Other data buses include, but are not limited to, Amazon Kinesis®, Google Pub/Sub®, and Microsoft Event Hubs®. Moreover, as will be described in greater detail below, this resource monitoring by resource manager 212 may provide the requisite information or data, e.g., time series counters and/or metrics from resources servicing the network from infrastructure 104, such as sensors. In the data collection phase, time-series data streams are provided to the data bus 208 from sensors, such as the physical and/or virtual resources implemented on the infrastructure 104 (e.g. NFs deployed on the network), which contain counters and metrics of performance of the physical and/or virtual resources. In the design phase, the assurance engine 206 applies historical data-streams as training data input into a machine learning (ML) algorithm and trains a plurality of anomaly detection models. Scoring is performed on the anomaly detection models, and the model having the optimal score is deployed on the production run-time machines (e.g., the physical and/or virtual resources implemented on the infrastructure 104) during an operationalization phase. Moreover, upon operationalization of the aforementioned production run-time models, resource manager 212 may begin to receive predictive notifications, e.g., early warning signals of impending system failure, degradation, etc.

Resource inventory 224 may comprise a data repository in which records including physical, logical, and/or virtual resources that are available to be used to implement a particular service(s). For example, resource inventory 224 may maintain information regarding infrastructure elements on which virtualized resources may be instantiated to realize a requested service that service fulfillment engine 204 seeks to fulfill/provision.

While logical and virtualized/containerized resources are discussed, it is to be understood that these will ultimately, e.g., at a low level of implementation detail, be implemented using physical computing, storage or network, i.e. hardware, resources. For example, a network function virtualization infrastructure may comprise virtual computing (e.g., processor), virtual storage (e.g., hard disk) and virtual network (e.g., virtual network interface controllers) resources implemented on a virtualization layer (e.g., implemented by one or more hypervisors or virtual machine monitors). The virtualization layer may then operate on hardware resources such as processor devices, storage devices and physical network devices, for example as provided by one or more server computer devices.

The resource manager 212, together with the resources defined in resource inventory 224, provide entity-action building blocks based on a physical and/or virtual infrastructure 104 that may be combined in the form of a descriptor to enable the provisioning of a service. Service fulfillment engine 204, as alluded to above, performs the requisite orchestration to provide the desired network function virtualization, while resource manager 212 determines how to orchestrate the resources for supporting the desired network function virtualization.

In FIG. 2, a data bus 208 may be used for messaging, storage, and enriching/processing of any data, e.g., counters and/or metrics from sensors in the infrastructure 104 arising from the resource monitoring of the services provisioned by the service fulfillment side of service director 202, which can be typical behavior of the resources, including any anomalous issues such as lost communications, lost service, resource failures, service quality level falling below a threshold, quality of user experience becoming unacceptable, etc. Service assurance engine 206, upon receiving time-series metrics and/or counters can apply an anomaly detection engine to identify issues and detect anomalous events to predict failure scenarios and determine how the service and/or resource can be healed by addressing the issues. Again, and as alluded to above, upon operationalization of production run-time models disclosed herein, system issues can be identified, anomalous issues detected, and notifications can be generated ahead of such system issues occurring. Service assurance engine 206 may send closed loop actions 206a (described above) to the fulfillment engine 204, effectuating a closed loop, so that fulfillment engine 204 can carry out the necessary actions to achieve the requisite service assurance.

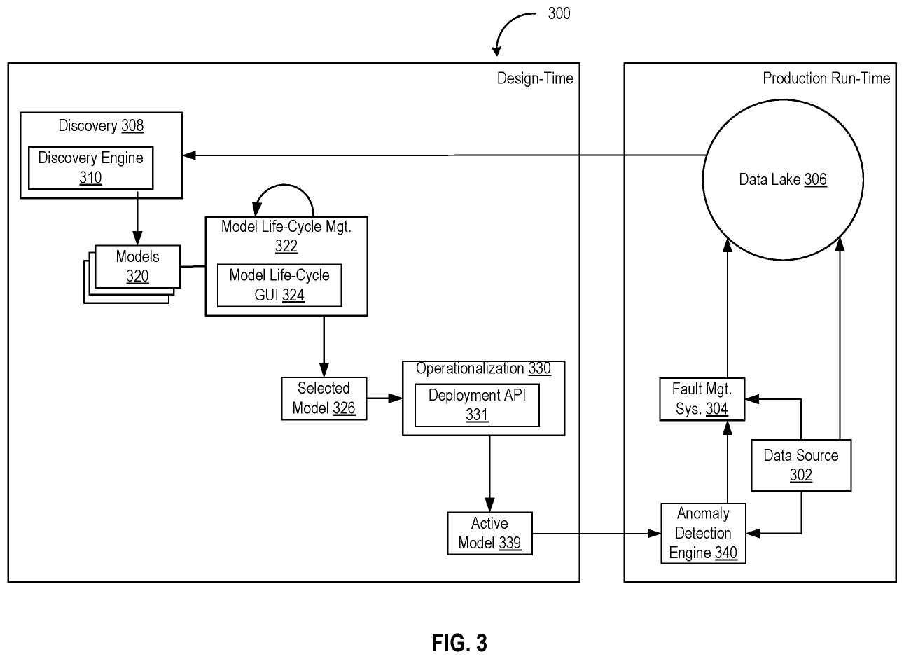

As alluded to above, anomalous issue detection and prediction of service degradation/outage for warning generation can be accomplished over the course of a discovery phase, an operationalization phase, and a production run-time phase. FIG. 3 is a schematic representation of a system architecture 300 embodying these three phases. As illustrated in FIG. 3, a data source 302 (which may represent one or more systems, system components, sensors, etc. from which issues, such as events, messages, log data can be received) contribute raw issue data to data lake 306. Data lake 306 can be a store for data, e.g., enterprise data, including, raw copies of source system data, and transformed data used for reporting visualization, analytics, machine learning, etc. Since both the volume and throughput of data, e.g., issues, such as messages or events, are large, tools and platforms that are capable of handling this volume and throughput may be used. Big data technologies are specifically engineered to address these needs and allow computational results to be generated in finite time, within the available computational resources, and data lake 306, in this context, may be used to persist or host incoming data, large in volume and high in throughput, which is subsequently processed by the systems methods described herein. Data lake 306 may aggregate information from one or more portions, aspects, components, etc. of a SP system (e.g., FIGS. 1 and 2). Alarm/incident-related information can also be received by data lake 306 from a fault management system 304. Assurance engine 206 (FIG. 2) may be thought of as an implementations of such fault management system 304. The alarm/incident-related information along with the raw event data, can be automatically analyzed, e.g., offline, during the discovery phase 308. A discovery engine 310 may implement the discovery phase, where statistical techniques are used to quantitatively qualify, and identify a failure scenario which lends itself to the possibility of predicting a service failure at a future point in time. Once failure scenario candidates have been identified, symptoms associated with the failure scenario candidates are scored, and early warning signal time frames can be estimated. In other words, discovery comprises mathematically framing a problem to be solved. This leads to the development of models 320 that can be trained.

Upon selection of a model (selected model 326), the operationalization phase 330 can commence. The operationalization phase can be effectuated by operationalization functions that serve to deploy production run-time machines or models, e.g., active model 339, reflecting the intelligence learned by discovery engine 310 using a deployment API 331. For example, some client or user which seeks a prediction (inference request) may input data to the API server (which may be using the Representational state transfer (REST) architecture or a remote procedure call (RPC) client). In return, the API server may output a prediction based on the active model 339.

Once such production run-time machines or models are operationalized, they can operate, collectively, as an anomaly detection engine 340 that in real-time, may analyze incoming issue data streams according to/using the production run-time machines having active model 339 running thereon and predict upcoming or future service degradation and/or outages based on identifying anomalous issues. Upon predicting such future service degradation/outages, anomaly detection engine 340 may output early warning signals in advance of the predicted service degradation/outages.

Moreover, the production run-time machines having models (e.g., active model 339) running thereon may, over time, lose prediction accuracy. Accordingly, in some implementations, the run-time production models may be re-calibrated, e.g., by retraining/relearning via repetition of the discovery phase. That is, with any machine learning model, changes in precision and accuracy of the prediction or inference can occur over time and that model may require retraining, e.g., go through the discovery and operationalization phases again. Additionally, changes in network behavior or network configurations may result in in changes in accuracy of predictions or inferences of the models (e.g., an active model 339). This may require generation of new models that are trained to better reflect reality, and produce predictions or inferences that are more meaningful and useful. That is, with any machine learning model, changes in reality can occur, such that the model may need to be retrained, e.g., go through the discovery and operationalization phases again, to provide optimal predictions and inferences. This can be referred to as the model life-cycle management 322, which may be referred to as a model quality assurance phase. In some implementations, recalibration of an active model 339 may be performed by the model life-cycle management 322 periodically (e.g., weekly, bi-weekly, monthly, etc.), or upon a user (e.g., customer or SP) request to recalibrate an active model. In other implementations, recalibration of an active model 339 may be performed by the model life-cycle management 322 in a case where the accuracy of the generated predictions falls below some accuracy threshold. For example, inference engine 340 may access fault management system 304 (described above) to compare generated predictions with the historical information regarding past service degradation, outages, and/or other service issues. If the accuracy of the generated predictions falls below the accuracy threshold (which may be user defined), the run-time production machines/models may be re-calibrated. In various implementations, a model life-cycle graphical user interface (GUI) 324 may be provided to allow a user input during the recalibration, for example, to initiate re-discovery and/or provide for re-operationalization. It should be noted that similar to the closed-loop aspect described above, such an implementation of various implementations also results in a closed-loop implementation between the discovery/design and production run-time phases.

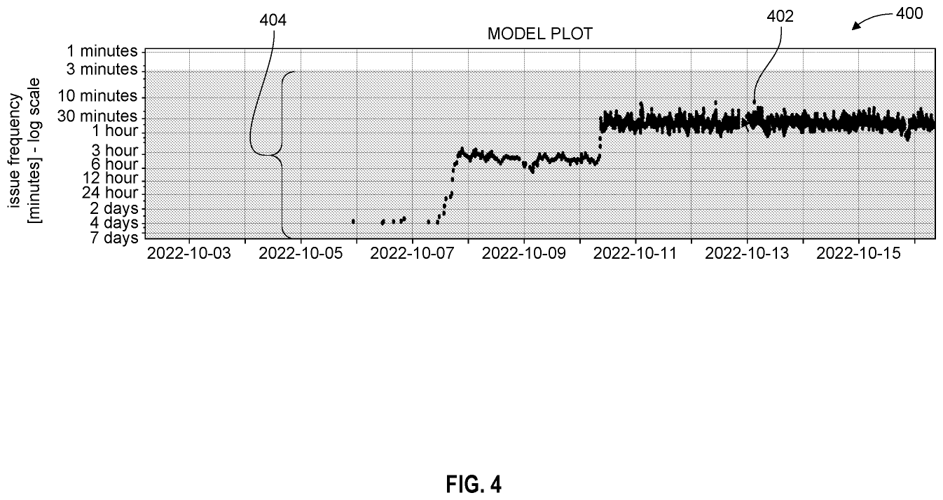

FIG. 4 illustrates an example graphical representation of a model plot 400 generated by a model according to an example implementation of the disclosed technology. The model plot 400 may be generated by an active model (e.g., active model 339 of FIG. 3) or by a selected model (such as, for example, a candidate model). The model plot 400 depicts time-series issue data 402 in the form of a frequency of an issue occurring (e.g., frequency that an issue is detected by the model) on a network over a time window. For example, model plot 400 depicts time-series data of DHCP_NO-OFFERS issues detected on the network, which are plotted according to a frequency of detecting the issue on the vertical axis over a time window on the horizontal axis. The vertical axis provides the issue frequency in minutes according to a logarithmic scale. Thus, model plot 400 depicts, over a given time window, frequencies at which an issue, as defined by the model, is detected on the network.

Model plot 400 also depicts an anomaly detection threshold 404, which is used by the model to identify an anomalous issue. For example, any issues that exceed the threshold may be indicative of an anomalous issue from which the model can identify an anomaly on the network, which may be used to predict service degradation or outage. The anomaly detection threshold 404 may be set according to user defined rules or based on standard deviations derived from the issue data. In some implementations, the anomaly detection threshold 404 may be a number of standard deviations (e.g., 5 standard deviations or other user defined number) from a central value of the time-series issue data. The central value may be a median value, mean value, or other value that is indicative of the central value of the time series data.

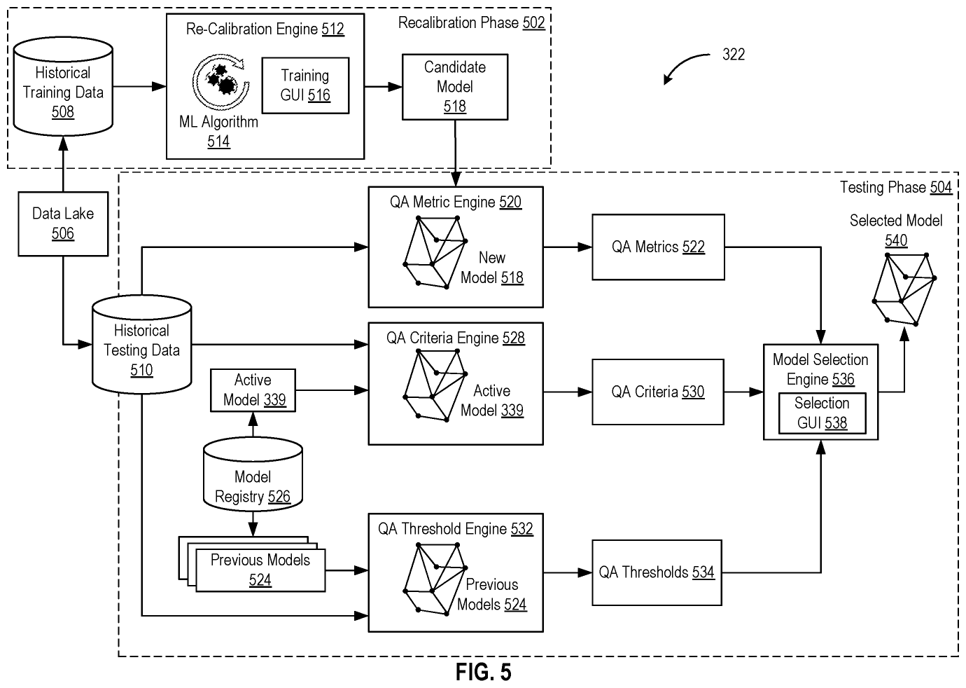

As alluded to above, anomaly detection can be accomplished over the course of a collection phase, a design phase, model quality assurance phase, an operationalization phase, and a production run-time phase. FIG. 5 is a schematic representation of an example architecture for model life-cycle management 322 embodying the model quality assurance phase. System 500 may be implemented, for example, as part of assurance engine 206 of FIG. 2. The model quality assurance phase may include a re-calibration phase 502 and a testing phase 504. The following description is made with reference to the model quality assurance phase executed for one currently deployed model (e.g., active 339 of FIG. 3) that is recalibrated according to the model life-cycle management 322. However, it will be appreciated the same or similar processes may be performed in tandem, parallel, and/or sequentially for any number of currently deployed models.

As illustrated in FIG. 5, data lake 506 (e.g., an example implementation of data lake 306 of FIG. 3) commits raw performance data to historical databases 508 and 510 during a collection phase, for example, via data bus 208 of FIG. 2. Databases 508 and 510 can store received data, such as raw performance data in the form of issues, such as, but not limited to, metrics, events, log messages, and/or counters, and convert the data to a format used for reporting visualization, analytics, machine learning, etc. Databases 508 and 510 retain historical performance data over a range of time periods that are representative of typical operational situations of the data sources 302. Typical operational situations should be representative of typical behavior over a given time window, which may include any number of failure scenarios, anomalous issues, and/or variations in network operation. Since both the volume and throughput of the data streams can be large, tools and platforms that are capable of handling this volume and throughput may be used, such as such as Apache Kafka®, Amazon Kinesis®, Google Pub/Sub®, Microsoft Event Hubs®, etc. Such technologies are engineered to address the needs of high throughput, large data volumes and allow computational results to be generated in real-time or near real-time at worst, within the available computational resources, and databases 508 and 510, in this context, may be used to persist or host incoming data, large in volume and high in throughput, which is subsequently processed by the systems methods described herein. Database 508 and database 510 may be a common database or discrete databases.

Examples of raw performance data includes CPU utilization, memory consumption, number of bytes/octets in/out, number of packets in/out, amongst several others. Some examples of raw counters include number of subscribers successfully registered/dropped/failed, number of active protocol data unit (PDU) sessions, amongst several others. Models may be trained to convert the raw performance data and counters into issue data, such as events, metrics, or the like.

Referring back to FIG. 3, according to some implementations, during the discovery phase (e.g., discovery phase 308) models 320 can be generated based on historical performance data, such as that stored in database 508. For example, historical performance data is retrieved by discovery engine 310 from the database 508 and applied as training data to a machine-learning algorithm, which generates models 320 trained on the historical performance data according to training parameters. Upon selection of a model (selected model 326), the operationalization phase 330 can commence and deploy an active model 339 onto run-time machines.

As described above, the active model 339 may need to be re-calibrated from time to time via the model quality assurance phase. To recalibrate a model, model life-cycle management 322, referring back to FIG. 5, executes re-calibration phase 502 to generate a new, candidate model 518 by retraining the ML algorithm used to generate the active model 339 and select an optimal model from the currently active model 339 and the candidate model 518 for deployment. For example, re-calibration engine 512 can apply historical performance data as training data to a ML algorithm 514, which generates candidate model 518 that is trained on the historical performance data according to training parameters. The ML algorithm 514 may be the same machine-learning algorithm used to generate the currently active model 339. The historical performance data retrieved by the re-calibration engine 512 may include the recent performance data, which is representative of the recent network operating conditions (e.g., behavior and/or configurations). For example, candidate model 518 may be generated using performance data acquired between when the active model 339 to a current time. Active model 339 may have been trained on data that does not include the recent performance data, while candidate model 518 is trained on at least the recent performance data. In some implementations, candidate model 518 may be trained on the recent performance data and previous data (e.g., the data used to train active model 339).

Training parameters, such as identification of a NF vendor and/or NF type may be used to retrieve performance data so to train new models 518 for the identified vendor and/or type. Additionally, to train models representative of anomalous situations experienced on the network, data samples spanning time windows over which representative of normal, expected network behaviors and configurations. As such, training parameters may include a time window for retrieving historical performance data within the window and the model can identify deviations from the normal, expected behavior as anomalous situations. In some examples, a time window of the most recent 1 month may be sufficient, while in other situations a smaller or larger window may be desired. In some implementations, a training GUI 516 may be provided to allow network operators to input training parameters.

The candidate model 518 represents a candidate for deployment on run-time machines. For example, candidate model 518 may be a candidate for replacing currently active model 339, for example, via the operationalization phase 330, as described above in connection with FIG. 3, to deploy candidate model 518 as an updated active model. For example, candidate model 518 may be compared with the currently active model 339 and an optimal model selected therefrom. In the case that candidate model 518 is optimal relative to the currently active model 339 (e.g., good enough at identifying anomalous issues as compared to the currently active model 339), the candidate model 518 deployed on anomaly detection engine 340 as an updated active model 339 via operationalization phase 330. In the case that the currently active model 339 is the optimal model, the run-time machines are not updated and the anomaly detection engine 340 operates according to the currently deployed model (e.g., currently active model 339).

During the testing phase 504, candidate model 518 is tested based on historical performance data stored in database 510. For example, historical performance data is retrieved by a quality assurance (QA) metric engine 520 from the database 510 and applied as testing data to the candidate model 518, which generates output data in the form of issue detection results and network failure prediction results from the issue detection results. For example, candidate model 518 outputs prediction results including issue detect results based on the testing data, which may be plotted according to a model plot, such as model plot 400. The testing data may be a subset of the historical training data used for generating candidate model 518 or may be a distinct set of historical data, for example, representative of most recent network operating conditions.

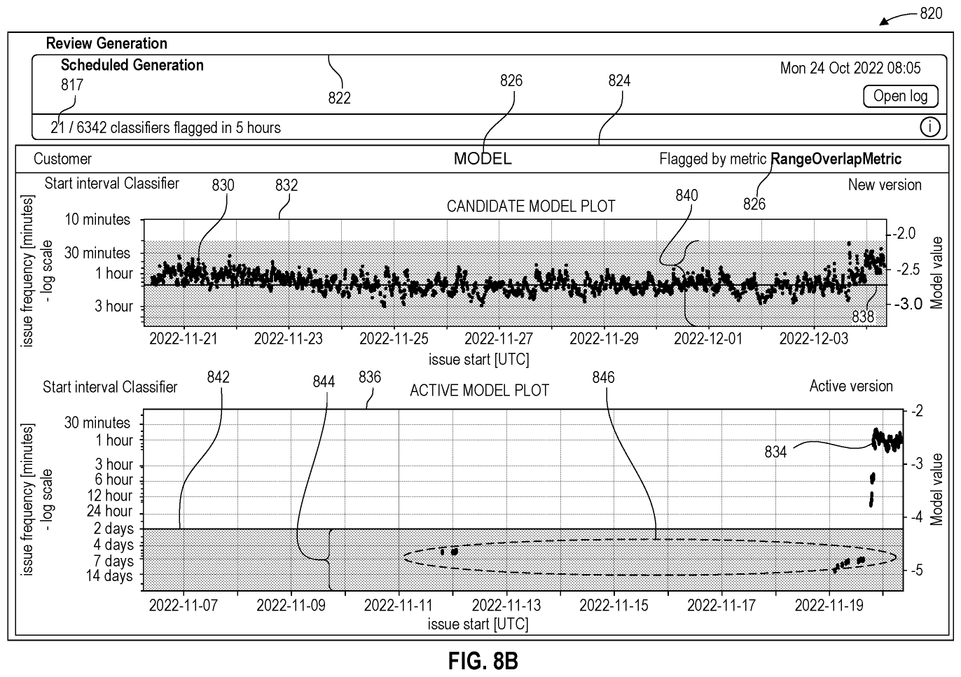

The QA metric engine 520 generates a plurality of QA metrics 522 for candidate model 518 from the issue detection results. For example, the metric engine 520 determines a first QA metric as a model value of the candidate model 518. The model value may be representative of a central value of the issue detection results for the candidate model 518. For example, the model value may be a central value of time-series issue data output by the candidate model 518 that is determined, for example, by calculating a mean value or a median value from issue detection results associated with the candidate model 518. FIG. 8B, discussed below, depicts an illustrative example of a model value as a first QA metric.

The QA metric engine 520 also determines a second QA metric for the candidate model 518 as a range of scale (also referred to herein as a width) of issue detection results associated with the respective candidate model 518. In an example, the scale may be based on standard deviations of differences between the data and the residuals of the model. In other examples, the scale may be determined as a median absolute deviation or from a statistical Gaussian scale estimator referred to as Qn. The range of the scale for the candidate model 518, for example, may be based on applying a factor (e.g., an integer multiplier) to the scale from the model value corresponding to the candidate model 518. The factor may be a multiplier that is applied to the scale to calculate the range of the scale, such as a numerical integer. In an example case, the factor may be five and the range of the scale may be set as five standard deviations from the model value. In some implementations, the second QA metric may correspond to an anomaly detection threshold of the candidate model 518, such as the anomaly detection threshold described in connection with FIG. 4. FIG. 8B, discussed below, depicts an illustrative example of a range of the scale as a second QA metric.

The testing phase 504 also generates QA criteria 530 and a plurality of QA thresholds 534 for evaluating the candidate model 518. For example, testing phase 504 may generates QA criteria 530 and plurality of QA thresholds 534 by applying testing data to the currently active model 339 and a plurality of previously deployed models 524. Currently active and previously deployed models may be stored in a model registry 526 such as a database, database partition, or other data repository. For example, with reference to FIG. 3, upon selecting a selected model 326 for deployment as an active model 339, the selected model 326 can be stored in model registry 526 and associated with any previously deployed models trained from a common ML algorithm. Similarly, previously deployed models (e.g., those models that were deployed on run-time machines and then replaced with an updated active model) can be stored in model registry 526. Thus, during testing phase 504 of FIG. 5, the currently active model 339 and a number of previously deployed models 524 corresponding to the candidate model 518 can be retrieved from model registry 526 by a QA criteria engine 528 and a QA threshold engine 532, respectively. The number of previously deployed models 524 may include any number of models that were deployed within a set time period prior generating candidate model 518 (e.g., 1 month prior, 2 months prior, etc.). The previously deployed models 524 may include the currently active model 339 as well, but does not include any of new models 518 (which have not yet been deployed).

Models are considered herein to correspond to one another when the models are generated from a common ML algorithm or common set of ML algorithms. For example, the candidate model 518 is generated from ML algorithm 514. A currently active model or previously deployed model are considered to correspond to the candidate model 518 if the currently active model or previously deployed model were generated from the same ML algorithm 514. Models may also be considered herein to correspond to one another when the models are generated from the same type of data. For example, data of the same kind of network problem (e.g., no DHCP offers, service unavailable, etc.); on the same network (e.g., Eduroam, etc.); and/or the same application/program (e.g., gmail.com, etc.)

The QA criteria engine 528 retrieves a currently active model 339 corresponding to the candidate model 518 and applies the testing data to the retrieved currently active model 339. For example, the testing data is retrieved by a QA criteria engine 528 from database 510 and applied the currently active model 339. The testing data is the same testing data as applied to the candidate model 518 to generate QA metrics 522. The currently active model 339 generates output data in the form of prediction results including issue detection results of a performance metric modeled by the currently active model 339 according to the testing data.

From the issue detection results output by the currently active model 339, the QA criteria engine 528 generates QA criteria 530. In various implementations, the QA criteria 530 may be a range of the scale from the model value determined from the issue detection results of the currently active model 339. Similar to the second QA metric described above, the range of the scale of the active model 339 may be a number of standard deviations from a model (or center) value of the issue detection results. The range of the scale may be representative of an anomaly detection threshold for the active model 339.

The QA threshold engine 532 retrieves previously deployed models 524 corresponding to the candidate model 518 and applies the testing data to the retrieved previously deployed models 524. For example, the testing data is retrieved by a QA threshold engine 532 from database 510 and is individually applied to each of the previously deployed models 524. The testing data is the same testing data as applied to the candidate model 518 to generate QA metrics 522. Each of the previously deployed models 524 currently generates respective output data in the form of respective prediction results and respective issue detection results of a performance metric modeled by each respective previously deployed models 524 according to the testing data.

From the issue detection results of the previously deployed models 524, the QA threshold engine 532 generates a plurality of QA thresholds 534. The plurality of QA thresholds 534 may be based on performance distributions derived from an aggregation of the issue detection results of the previously deployed model 524 collectively. A first QA threshold may be derived from a first performance distribution based on model values and a second QA threshold may be derived from a second performance distribution based on ranges of the scales.

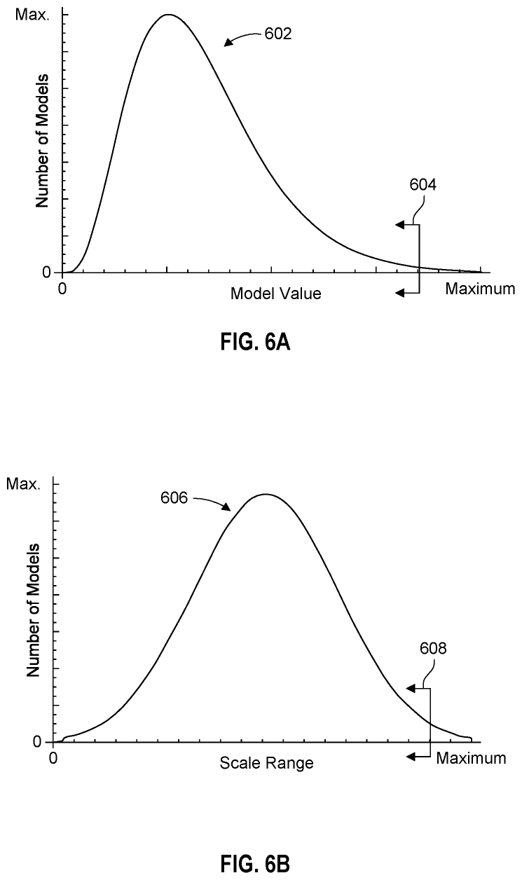

For example, the first QA threshold may be based on a first performance distribution of model values indicative of issue detection results associated with each of the previously deployed models 524. A model value can be determined for each previously deployed model from the issue detection results of each respective previously deployed model. The model value may be a central value indicative of the issue detection results, for example, a mean or median value of issue detection results associated with a respective previously deployed model 524. The model values may be combined to form a first performance distribution. FIG. 6A illustrates an example first performance distribution 602 derived from model values of previously deployed models 524. As shown in FIG. 6A, a count of models is plotted as a function of model values to provide distribution 602. From the distribution 602, the first threshold may be set as a model value corresponding to a first percentile of the distribution 602. For example, as shown in FIG. 6A, a first threshold 604 may be set as the model value delineating the 99th percentile. Other percentiles may be used to set a model value as the first threshold, for example, 85th percentile, 90th percentile, 95th percentile, etc.) depending on the desired application and tolerances.

The second QA threshold may be based on a second performance distribution of ranges of the scales of the issue detection results associated with each of the previously deployed models 524. Each range of the scale may be determined, as described above, as a factor (e.g., 5 in some examples) applied to the scale associated with a respective previously deployed model 524, such as standard deviations from the model value associated with a respective previously deployed model 524, as a median absolute deviation associated with a respective previously deployed model 524, or from the statistical Gaussian scale estimator referred to as Qn associated with a respective previously deployed model 524. As described above, the range of the scale of each previously deployed model 524 may be indicative of the anomaly detection threshold of each previously deployed models 524. The ranges of the scales may be combined to form a second performance distribution. FIG. 6B illustrates an example second performance distribution 606 derived from ranges of the scales (referred to as scale range in FIG. 6B) of previously deployed models 524. As shown in FIG. 6B, a count of models is plotted as a function of scale range to provide distribution 606. From the distribution 606, the second threshold may be set as a scale range corresponding to a second percentile of the distribution 606. For example, as shown in FIG. 6B, a second threshold 608 may be set as the scale range delineating the 99th percentile. Other percentiles may be used to set a scale range as the second threshold, for example, 85th percentile, 90th percentile, 95th percentile, etc.) depending on the desired application and tolerances. The first and second QA thresholds are shown as being the same, but they may be different according to a desired application.

Testing phase 504 includes model selection engine 536, which is configured to select an optimal model from the candidate model 518 and active model 339 based on the QA metrics 522, QA criteria 530, and the plurality of QA thresholds 534. The model selection engine 536 ingests the QA metrics 522 associated with the candidate model 518 and evaluates the candidate model 518 by through a comparison of the QA metrics 522 against (a) the QA criteria 530 and (b) the plurality of QA thresholds 534 to determine if the candidate model 518 is an optimal relative to the currently active model 339. For example, the model selection engine 536 compares: (i) the first QA metric to the first QA threshold, and determines if the first QA metric is less than the first QA threshold; (ii) the second QA metric to the second QA threshold, and determines if the second QA metric is less than the second QA threshold; and (iii) the second QA metric to the QA criteria, and determines if the second QA metric in view of the first QA metric overlap with the QA criteria. In the case that the QA metrics 522 satisfy all three QA conditions, the model selection engine 536 determines the candidate model 518 is optimal relative to currently active model 339. Alternatively, in the case that the QA metrics 522 fails any of the above QA conditions, model selection engine 536 determines the currently active model 339 is optimal relative to the 518.

In an illustrative example, the model selection engine 536 receives a first QA metric as a model value of the candidate model 518 and a second QA metric as a scale range of the issue detection results of the candidate model 518. The model selection engine 536 also receives a first QA threshold as a model value corresponding to the first percentile of the first performance distribution (e.g., the model value of the 99th percentile of model values in one example) and a second QA threshold as a scale range corresponding to the second percentile of the second performance distribution (e.g., the scale range of the 99th percentile of scale ranges in one example). If the model value of the candidate model 518 is less than the model value corresponding to the first percentile, the candidate model 518 is considered to satisfy this threshold QA condition. If the scale range of the candidate model 518 is less than the scale range corresponding to the second percentile, the candidate model 518 is considered to satisfy this QA threshold condition.

Further, model selection engine 536 receives the QA criteria as the variance scale of the currently active model 339. If the scale range from the model value of the candidate model 518 overlaps with the scale range from the model value of the currently active model 339, the candidate model 518 is considered to satisfy this QA criteria condition. For example, the range of the scale spans between a minimum value and a maximum value, where the maximum value determined by applying the factor to the scale (e.g., factor times the scale) and adding the result to the model value and a minimum value determined by applying the factor to the scale and subtracting the result from the model value. In an illustrative example, assume that the candidate model 518 has range of the scale with a minimum value of 6 and a maximum value of 8, while the active model 339 has range of the scale with a minimum value of 8.5 and a maximum value of 10. Thus, in this example, the ranges do not overlap and thus the QA criteria condition is not satisfied. However, if the candidate model 518 in the above example, had a maximum value of 9, then the QA criteria condition is satisfied since the range of the scale for the candidate model 518 overlaps with the range of the scale for the active model 339.

If the candidate model 518 is the optimal model, the model selection engine 536 selects the candidate model 518 as the selected model 540. The selected model 540 is provided to operationalization phase 330 as selected model 326 of FIG. 3, and the operationalization phase 330 automatically commences to deploy the selected model 326 onto production run-time machines as active model 339. As used herein, “automatically” or “automatic” refers to performing all necessary steps and operations to execute an automatic functionality without requiring additional or subsequent human or external input, activation, or control. For example, in the above scenario, the selected model 540 can be deployed onto anomaly detection engine 340 on production run-time machines without human or external intervention responsive to a determination that the candidate model 518 is optimal with respect to active model 339.

If the currently active model 339 is the optimal model, the model selection engine 536 selects the currently active model 339 as the selected model 540. In some implementations, the selected model 540 is provided to the operationalization phase 330 as selected model 326. In this case, since the selected model 326 is the same as the currently active model 339, there is no need to deploy the model.

In some implementations, the model selection engine 536 may generate an alert responsive to the determination that the currently active model 339 is the optimal model relative to the candidate model 518. The alert may be utilized to notify a human operator (e.g., SP operator) that the candidate model 518 failed to satisfy one or more of the QA thresholds 534 and/or QA criteria 530 and is therefore not optimal for automatic deployment. In some implementations, a selection GUI 538 (see FIGS. 8A and 8B below) may be provided to review the candidate model 518 with the currently active model 339. The model selection engine 536 may provide the generated alert to the selection GUI 538, which presents the alert to an operator, e.g., through visual presentation, audio presentation, tactical feedback, etc. The operator may utilize selection GUI 538 to perform a visual comparison of the prediction results, such as the issue detection results in this example, from the active model 339 again the candidate model 518, and decide on whether or not to deploy the candidate model 518. If the operator determines the candidate model 518 is in fact the optimal model, the selection GUI 538 can be utilized by the operator to input a command to deploy the candidate model 518.

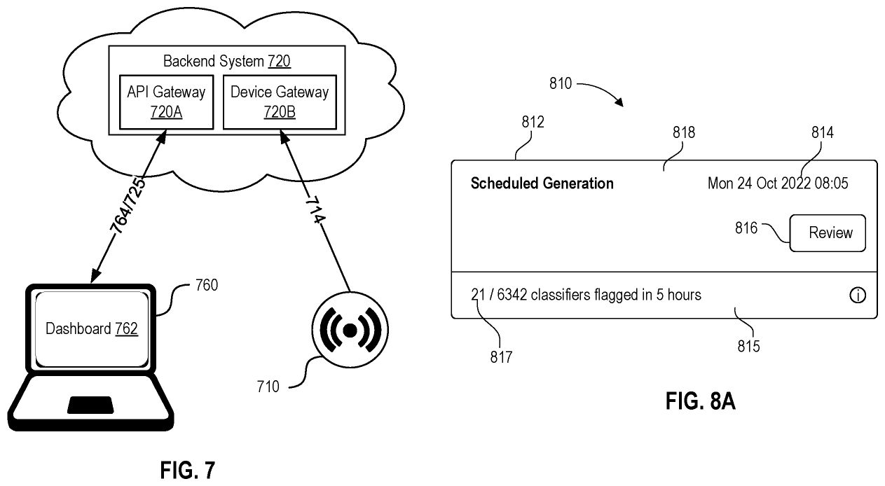

FIG. 7 illustrates an example of sensor 710 communicating performance data to a backend system 720 on or in which a frontend system 760 may be implemented or presented, e.g., to an end-user (such as a SP operator). For example, a SP may provide service filament and service assurance on network 704 and may have an interest in monitoring services via performance metrics from sensors 710 (e.g., physically and/or virtually-implemented resources as described above in connection with FIG. 2). In this regard, the backend system 720 may comprise assurance engine 206, including system architecture 300. The SP may receive alert notifications via dashboard 262, for example, responsive to a determination that a candidate model is not optimal with respect to a currently active model. Once an alert notification is received, the frontend system 760 may present a selection GUI (e.g., GUI 538) on dashboard 762 from which the SP may review the candidate model in view of the currently active model and select whether or not to deploy the candidate model. Once set, the selection action can be uploaded from the frontend system 760 to the backend system 720.

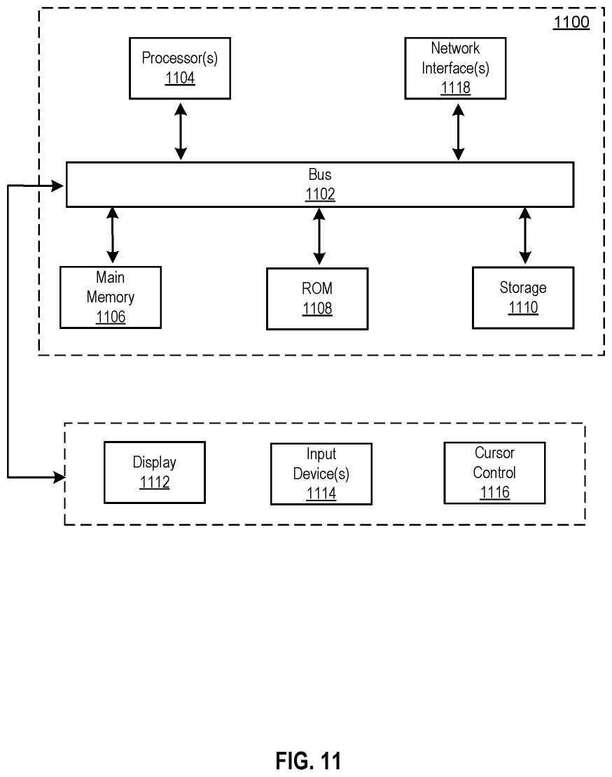

Sensors 710 may connect to backend system 720 via device gateway 720B. In particular, sensor 710 may transmit raw performance data 714 to backend system 720. The API gateway 720A of backend system 720 may then forward or transmit an alert notification 725 to frontend system 760. The API gateway 720A may also forward prediction results and issue detection results generated, for example, by the candidate model 518, currently active model 339, and previously deployed models 524, along with QA metrics 522, QA criteria 530, and QA thresholds 534. The information may be presented to an operator via dashboard 762. The frontend system 760 may forward or transmit user selections and inputs 764 to API gateway 720A, including a command indicating whether or not to deploy a candidate model 518. The frontend system 760 may be a computer, workstation, laptop, or other computing/processing system or component capable of receiving and presenting such information/data, such as, for example, computer system 1100 described below in connection with FIG. 11.

FIGS. 8A and 8B are example visualizations generated by a GUI for selecting an a model for deployment according to implementations of the disclosed technology. FIGS. 8A and 8B illustrate examples display panes of selection GUI 538 of the model life-cycle management 322 that may be used present an alert generated by model selection engine 536 for a candidate model that failed one or more QA conditions as explained in connection with FIG. 5 above and to select whether or not to deploy the candidate model.

FIG. 8A illustrates a first display pane 810 of the GUI. First display pane 810 comprises at least one box 812 for a scheduled model generation. The scheduled model generation may be indicative of a scheduled execution of model life-cycle management 322 in which a number of candidate models are generated (e.g., 6,342 candidate models in this example). While FIG. 8A depicts a single box 812, implementations disclosed herein may include a number of scheduled generations, such as future scheduled model generations and/or prior scheduled model generations.

A first portion 815 is provided in which a notification 817 is presented to the user based on one or more alerts generated by model selection engine 536. For example, for each generated candidate model that fails one or more QA conditions as described in connection with FIG. 5, model selection engine 536 generates an alert that is provided to the GUI and presented to the user, for example, as a counter of a number of candidate models that have been flagged for the scheduled candidate model generation. In the example of FIG. 8A, 21 candidate models were flagged and generated an alert out of the 6,342 candidate models generated.

A second portion 818 is also provided in which a date 814 for the scheduled model generation is presented. Second portion 818 also includes a review activation icon 816, which an operator may interact with (e.g., via mouse click, tap, swipe, etc.) to active a second display pane 820, shown in FIG. 8B, from which flagged candidate models can be reviewed by a service provider.

Second display pane 820 of the GUI provides a first portion 822 comprising a summary of the scheduled model generation, date therefor, and notification 817. The second display pane 820 also includes a second portion 824 comprising one or more comparison regions 826. Each comparison region 826 is provided for reviewing a flagged candidate model (e.g., labeled as new version in this example), for which model selection engine 536 generated an alert relative to a currently active model (e.g., labeled as active version in this example). Flagged candidate model may be an example of the candidate model 518 and currently active model may be an example of currently active model 339. A notification 828 of the QA threshold or criteria which the candidate model failed is also displayed. For example, notification 828 is provided as “RangeOverlapMetric”, which indicates that the scale range of the candidate model did not overlap with the scale range of the active model.

In the illustrative example of FIG. 8B, the flagged candidate model generated output data in the form of issue detection results 830 displayed as model plot 832. The active model generated output data in the form of issue detection results 834 displayed as model plot 836. Model plots 832 and 836 may be similar to model plot 400 of FIG. 4. The GUI also displays a model value 838 and scale range 840 for the flagged candidate model and a model value 842 and scale range 844 for the active model. Thus, a SP can visually compare issue detection results and QA metrics for a flagged candidate model against the QA criteria for an active model and determine, based on the visually analysis, whether or not to deploy the flagged candidate model. For example, in the illustrative example, the scale range 840 and 844 do not overlap. However, from visual inspection, the service provider may determine that scale ranges do not overlap due extenuating scenarios, such as outdated data points 846 in the active model shown in this example. The data points 846 may be the results of changes in the network overtime resulting in the data points 846. Since the data has changes significantly overtime, the candidate model has changed significantly and does not reflect these data points 846, which resulted in the candidate model being flagged for failing to satisfy a QA criteria condition. However, in this illustrative case, the flagged candidate model may be determined by the SP as optimal since the candidate model did not predict such outdated data, which resulted in low accuracy in the active model. Thus, the candidate model is in fact optimal with respect to the active model, even though it failed the QA criteria.

FIG. 8B illustrates one example comparison region 826, yet Implementations disclosed herein are not limited to one comparison region 826. The second display pane 820 may display any number of comparison regions 826, each corresponding to a flagged candidate model.

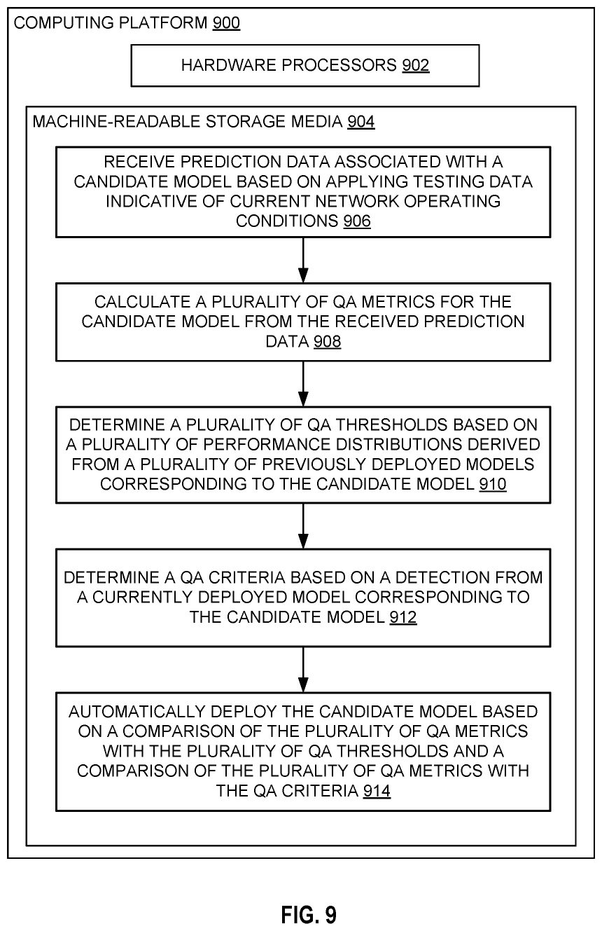

FIG. 9 illustrates an example computing component that may be used to implement automated model quality assurance and deployment in accordance with various implementations. Referring now to FIG. 9, computing component 900 may be, for example, a server computer, a controller, or any other similar computing component capable of processing data. In the example implementation of FIG. 9, the computing component 900 includes a hardware processor 902, and machine-readable storage medium for 904.

Hardware processor 902 may be one or more central processing units (CPUs), semiconductor-based microprocessors, and/or other hardware devices suitable for retrieval and execution of instructions stored in machine-readable storage medium 904. Hardware processor 902 may fetch, decode, and execute instructions, such as instructions 906-914, to control processes or operations for automated model quality assurance and deployment. As an alternative or in addition to retrieving and executing instructions, hardware processor 902 may include one or more electronic circuits that include electronic components for performing the functionality of one or more instructions, such as a field programmable gate array (FPGA), application specific integrated circuit (ASIC), or other electronic circuits.

A machine-readable storage medium, such as machine-readable storage medium 904, may be any electronic, magnetic, optical, or other physical storage device that contains or stores executable instructions. Thus, machine-readable storage medium 904 may be, for example, Random Access Memory (RAM), non-volatile RAM (NVRAM), an Electrically Erasable Programmable Read-Only Memory (EEPROM), a storage device, an optical disc, and the like. In some implementations, machine-readable storage medium 904 may be a non-transitory storage medium, where the term “non-transitory” does not encompass transitory propagating signals. As described in detail below, machine-readable storage medium 904 may be encoded with executable instructions, for example, instructions 906-914.

Hardware processor 902 may execute instruction 906 to receive prediction data associated with a candidate model based on applying testing data indicative of current network operating conditions. For example, as described above in connection with FIGS. 3 and 5, a candidate model 518 is generated by model life-cycle management 322 during re-calibration phase 502 of the model quality assurance phase. The candidate model 518 then generates network failure prediction results including issues detected from testing data (e.g., data retrieved from database 510).

Hardware processor 902 may execute instruction 908 to calculate a plurality of QA metrics for the candidate model from the received prediction data. For example, as described above in connection with FIG. 5, QA metrics can be calculated from the network failure prediction results from the candidate model 518 by metric engine 520, which generates QA metrics 522. QA metrics 522 can comprises a first QA metric, such as a model value for candidate model 518, and a second QA metric, such as scale range of the candidate model 518.

Hardware processor 902 may execute instruction 910 to determine a plurality of QA thresholds based on a plurality of performance distributions derived from a plurality of previously deployed models corresponding to the candidate model. The plurality of performance distributions can be based on applying the testing data to each of the plurality of previously deployed models. For example, as described above in connection with FIG. 5, QA threshold engine 532 can apply the testing data, applied to candidate model 518 in instruction 908, to each of the plurality of previously deployed models 524 to generate a first performance distribution of model values of the plurality of previously deployed models, and a second performance distribution of scale range of the plurality of previously deployed models. From the performance distributions, the QA threshold engine 532 sets a first threshold as a model value corresponding to a first percentile of the first performance distribution and a second threshold as a scale range corresponding to a second percentile of the second performance distribution.

Hardware processor 902 may execute instruction 912 to determine a QA criteria based on a prediction from a currently deployed model corresponding to the candidate model based on applying the testing data to the active model (e.g., currently deployed mode). For example, as described above in connection with FIG. 5, QA criteria engine 528 can apply the testing data, applied to candidate model 518 in instruction 908, to currently active model 339, which output network failure prediction results comprising detected issues from the testing data. From the network failure prediction results, the QA criteria engine 528 determines a model value and a scale range for the currently active model 339 as the QA criteria 530.

Hardware processor 902 may execute instruction 914 to automatically deploy the candidate model based on a comparison of the plurality of QA metrics with the plurality of QA thresholds and a comparison of the plurality of QA metrics with the QA criteria. For example, as described in connection with FIG. 5, model selection engine 536 checks whether the candidate model 518 satisfies each of a plurality of QA conditions, and deploys the candidate model 518 on to production run-time machines via operationalization phase 330 if all QA conditions are satisfied. In an illustrative example, a first QA condition is satisfied if the first QA metric of the candidate model 518 is less than the first QA threshold; a second QA condition is satisfied if the scale range of the candidate model 518 is less than the second QA threshold; and a third QA condition is satisfied if the second QA metric overlaps with the QA criteria. If candidate model 518 fails to satisfy any of the plurality of QA conditions, then the candidate model 518 is flagged and an alert is generated to notify an operator for further review.

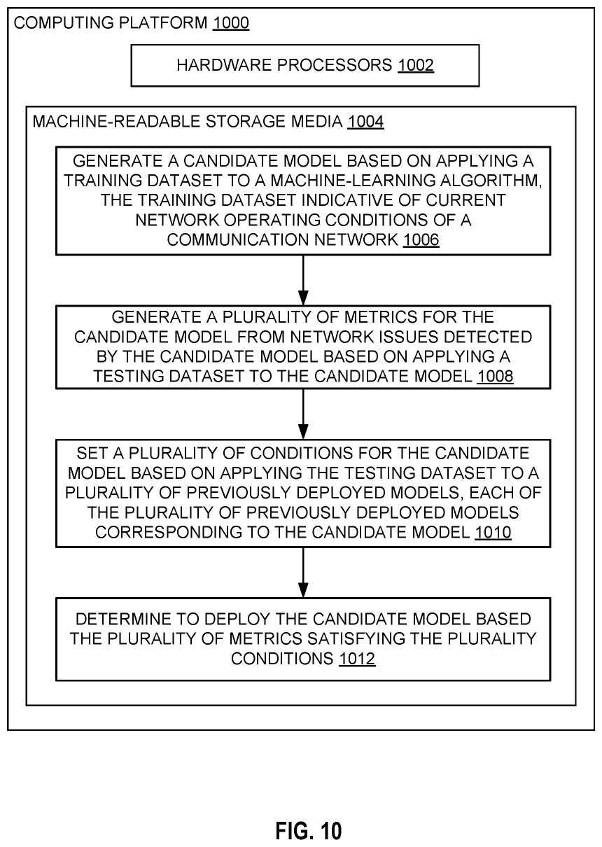

FIG. 10 illustrates an example computing component that may be used to implement automated model quality assurance and deployment in accordance with various implementations. Referring now to FIG. 10, computing component 1000 may be, for example, a server computer, a controller, or any other similar computing component capable of processing data. In the example implementation of FIG. 10, the computing component 1000 includes a hardware processor 1002, and machine-readable storage medium for 1004.

Hardware processor 1002 may be one or more central processing units (CPUs), semiconductor-based microprocessors, and/or other hardware devices suitable for retrieval and execution of instructions stored in machine-readable storage medium 1004. Hardware processor 1002 may fetch, decode, and execute instructions, such as instructions 1006-1012, to control processes or operations for automated model quality assurance and deployment. As an alternative or in addition to retrieving and executing instructions, hardware processor 1002 may include one or more electronic circuits that include electronic components for performing the functionality of one or more instructions, such as a field programmable gate array (FPGA), application specific integrated circuit (ASIC), or other electronic circuits.

A machine-readable storage medium, such as machine-readable storage medium 1004, may be any electronic, magnetic, optical, or other physical storage device that contains or stores executable instructions. Thus, machine-readable storage medium 1004 may be, for example, Random Access Memory (RAM), non-volatile RAM (NVRAM), an Electrically Erasable Programmable Read-Only Memory (EEPROM), a storage device, an optical disc, and the like. In some implementations, machine-readable storage medium 1004 may be a non-transitory storage medium, where the term “non-transitory” does not encompass transitory propagating signals. As described in detail below, machine-readable storage medium 1004 may be encoded with executable instructions, for example, instructions 1006-1012.

Hardware processor 1002 may execute instruction 1006 to generate a candidate model based on applying a training dataset to a machine-learning algorithm, the training dataset indicative of current network operating conditions of a communication network. For example, re-calibration phase 502 of FIG. 5 may be executed to recalibrate a model by generating a new, candidate model as described in connection with FIG. 5.

Hardware processor 1002 may execute instruction 1008 to generate a plurality of metrics for the candidate model from network issues detected by the candidate model based on applying a testing dataset to the candidate model. For example, as described above in connection with FIG. 5, a first metric of the plurality of metrics may be a model value of the candidate model generated from prediction results of the candidate model based on applying a testing dataset thereto to identify and/or detect issues. A second metric may be a scale range of the candidate model generated from prediction results of the candidate model.

Hardware processor 1002 may execute instruction 1010 to set a plurality of conditions for the candidate model based on applying the testing dataset to a plurality of previously deployed models, each of the plurality of previously deployed models corresponding to the candidate model. For example, as described above in connection with FIG. 5, a first condition may be based on a first threshold that can be set as a model value of a percentile of a first performance distribution derived from prediction results of the plurality of previously deployed models. A second condition may be based on a second threshold that can be set as a scale range of a percentile of a second performance distribution derived from prediction results of the plurality of previously deployed models. A third condition may be based on overlapping between the plurality of metrics and a scale range derived from prediction results of a currently active model corresponding to the candidate model. The currently active model may be included as one of the previously deployed models.

Hardware processor 1002 may execute instruction 1012 to determine to deploy the candidate model based the plurality of metrics satisfying the plurality conditions. For example, as described above in connection with FIG. 5, the candidate model can be automatically deployed onto production run-time machines responsive to the plurality of metrics satisfying each of the plurality of conditions. Alternatively, if the plurality of metrics fails one or more of the plurality of conditions, an alert can eb generated to notify an operator for further review.

FIG. 11 depicts a block diagram of an example computer system 1100 in which various of the implementations described herein may be implemented. The computer system 1100 includes a bus 1102 or other communication mechanism for communicating information, one or more hardware processors 1104 coupled with bus 1102 for processing information. Hardware processor(s) 1104 may be, for example, one or more general purpose microprocessors.

The computer system 1100 also includes a main memory 1106, such as a random access memory (RAM), cache and/or other dynamic storage devices, coupled to bus 1102 for storing information and instructions to be executed by processor 1104. Main memory 1106 also may be used for storing temporary variables or other intermediate information during execution of instructions to be executed by processor 1104. Such instructions, when stored in storage media accessible to processor 1104, render computer system 1100 into a special-purpose machine that is customized to perform the operations specified in the instructions.

The computer system 1100 further includes a read only memory (ROM) 1108 or other static storage device coupled to bus 1102 for storing static information and instructions for processor 1104. A storage device 1110, such as a magnetic disk, optical disk, or USB thumb drive (Flash drive), etc., is provided and coupled to bus 1102 for storing information and instructions.

The computer system 1100 may be coupled via bus 1102 to a display 1112, such as a liquid crystal display (LCD) (or touch screen), for displaying information to a computer user. An input device 1114, including alphanumeric and other keys, is coupled to bus 1102 for communicating information and command selections to processor 1104. Another type of user input device is cursor control 1116, such as a mouse, a trackball, or cursor direction keys for communicating direction information and command selections to processor 1104 and for controlling cursor movement on display 1112. In some implementations, the same direction information and command selections as cursor control may be implemented via receiving touches on a touch screen without a cursor.

The computing system 1100 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

In general, the word “component,” “engine,” “system,” “database,” data store,” and the like, as used herein, can refer to logic embodied in hardware or firmware, or to a collection of software instructions, possibly having entry and exit points, written in a programming language, such as, for example, Java, C or C++. A software component may be compiled and linked into an executable program, installed in a dynamic link library, or may be written in an interpreted programming language such as, for example, BASIC, Perl, or Python. It will be appreciated that software components may be callable from other components or from themselves, and/or may be invoked in response to detected events or interrupts. Software components configured for execution on computing devices may be provided on a computer readable medium, such as a compact disc, digital video disc, flash drive, magnetic disc, or any other tangible medium, or as a digital download (and may be originally stored in a compressed or installable format that requires installation, decompression or decryption prior to execution). Such software code may be stored, partially or fully, on a memory device of the executing computing device, for execution by the computing device. Software instructions may be embedded in firmware, such as an EPROM. It will be further appreciated that hardware components may be comprised of connected logic units, such as gates and flip-flops, and/or may be comprised of programmable units, such as programmable gate arrays or processors.

The computer system 1100 may implement the techniques described herein using customized hard-wired logic, one or more ASICs or FPGAS, firmware and/or program logic which in combination with the computer system causes or programs computer system 1100 to be a special-purpose machine. According to one implementation, the techniques herein are performed by computer system 1100 in response to processor(s) 1104 executing one or more sequences of one or more instructions contained in main memory 1106. Such instructions may be read into main memory 1106 from another storage medium, such as storage device 1110. Execution of the sequences of instructions contained in main memory 1106 causes processor(s) 1104 to perform the process steps described herein. In alternative implementations, hard-wired circuitry may be used in place of or in combination with software instructions.

The term “non-transitory media,” and similar terms, as used herein refers to any media that store data and/or instructions that cause a machine to operate in a specific fashion. Such non-transitory media may comprise non-volatile media and/or volatile media. Non-volatile media includes, for example, optical or magnetic disks, such as storage device 1110. Volatile media includes dynamic memory, such as main memory 1106. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same.

Non-transitory media is distinct from but may be used in conjunction with transmission media. Transmission media participates in transferring information between non-transitory media. For example, transmission media includes coaxial cables, copper wire and fiber optics, including the wires that comprise bus 1102. Transmission media can also take the form of acoustic or light waves, such as those generated during radio-wave and infra-red data communications.

The computer system 1100 also includes a communication interface 1118 coupled to bus 1102. Network interface 1118 provides a two-way data communication coupling to one or more network links that are connected to one or more local networks. For example, communication interface 1118 may be an integrated services digital network (ISDN) card, cable modem, satellite modem, or a modem to provide a data communication connection to a corresponding type of telephone line. As another example, network interface 1118 may be a local area network (LAN) card to provide a data communication connection to a compatible LAN (or WAN component to communicated with a WAN). Wireless links may also be implemented. In any such implementation, network interface 1118 sends and receives electrical, electromagnetic or optical signals that carry digital data streams representing various types of information.

A network link typically provides data communication through one or more networks to other data devices. For example, a network link may provide a connection through local network to a host computer or to data equipment operated by an Internet Service Provider (ISP). The ISP in turn provides data communication services through the world wide packet data communication network now commonly referred to as the “Internet.” Local network and Internet both use electrical, electromagnetic or optical signals that carry digital data streams. The signals through the various networks and the signals on network link and through communication interface 1118, which carry the digital data to and from computer system 1100, are example forms of transmission media.

The computer system 1100 can send messages and receive data, including program code, through the network(s), network link and communication interface 1118. In the Internet example, a server might transmit a requested code for an application program through the Internet, the ISP, the local network and the communication interface 1118.

The received code may be executed by processor 1104 as it is received, and/or stored in storage device 1110, or other non-volatile storage for later execution.

Each of the processes, methods, and algorithms described in the preceding sections may be embodied in, and fully or partially automated by, code components executed by one or more computer systems or computer processors comprising computer hardware. The one or more computer systems or computer processors may also operate to support performance of the relevant operations in a “cloud computing” environment or as a “software as a service” (SaaS). The processes and algorithms may be implemented partially or wholly in application-specific circuitry. The various features and processes described above may be used independently of one another, or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed example implementations. The performance of certain of the operations or processes may be distributed among computer systems or computers processors, not only residing within a single machine, but deployed across a number of machines.

As used herein, a circuit might be implemented utilizing any form of hardware, software, or a combination thereof. For example, one or more processors, controllers, ASICs, PLAS, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality. Where a circuit is implemented in whole or in part using software, such software can be implemented to operate with a computing or processing system capable of carrying out the functionality described with respect thereto, such as computer system 1100.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain implementations include, while other implementations do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

What is claimed is:

1. A method for automated model quality assurance, the method comprising:
receiving network failure prediction data associated with a candidate model based on applying testing data indicative of current network operating conditions;
calculating a plurality of quality assurance metrics for the candidate model from the received prediction data;
determining a plurality of thresholds based on a plurality of performance distributions derived from a plurality of previously deployed models corresponding to the candidate model, the plurality of performance distributions based on applying the testing data to each of the plurality of previously deployed models;
determining a criteria based on a prediction from a currently deployed model corresponding to the candidate model based on applying the testing data to the currently deployed model; and
automatically deploying the candidate model based on a comparison of the plurality of quality assurance metrics with the plurality of thresholds and a comparison of the plurality of quality assurance metrics with the criteria,
wherein each of the currently deployed model, the candidate model, and the plurality of previously deployed models are configured to predict failure scenarios of a network by detecting anomalous issues occurring on the network from real-time data from network functions.

2. The method of claim 1, further comprising:
automatically deploying the candidate model in response to the plurality of quality assurance metrics satisfying the plurality of thresholds and the plurality of quality assurance metrics satisfying the criteria.

3. The method of claim 2, further comprising:
generating an alert in response to one or more of: at least one of the plurality of quality assurance metrics failing to satisfy at least one of the plurality the thresholds and at least one of the plurality of quality assurance metrics failing to satisfy the criteria.

4. The method of claim 3, further comprising:
responsive to the alert, generating a visualization comprising a graphical user interface configured to display issue detection results from the candidate model and issue detection results of the currently deployed model, wherein a notification of the alert is provided by the graphical user interface.

5. The method of claim 4, further comprising:
deploying the candidate model responsive to an input that is based on the visualization of the candidate model and the currently deployed model.

6. The method of claim 1, wherein the plurality of quality assurance metrics for the candidate model comprises a value for the candidate model indicative of the prediction data associated with the candidate model and a scale range of the prediction data associated with the candidate model.

7. The method of claim 6, wherein the plurality of thresholds comprises:
a first threshold based on a first performance distribution of values indicative of prediction data associated with each of the plurality of previously deployed models, and
a second threshold based on a second performance distribution of scale ranges of the prediction data associated with each of the plurality of previously deployed models.

8. The method of claim 7, wherein the criteria comprises a scale range of the prediction data associated with the currently deployed model.

9. The method of claim 8, further comprising:
determining that the candidate model satisfies a first condition where the value of the candidate model is less than value corresponding to a first percentile of the first performance distribution;
determining that the candidate model satisfies a second condition where the scale range of the candidate model is less than a scale range corresponding to a second percentile of the second performance distribution; and
determining that the candidate model satisfies a third condition where the scale range of the candidate model overlaps with the scale range of the currently deployed model,
wherein the candidate model is automatically deployed responsive to determining the candidate model satisfied the first, second, and third conditions.

10. A system for automated model quality assurance, comprising:
at least one memory configured to store instructions; and
one or more processors communicably coupled to the memory and configured to execute the instruction to:
receive network failure prediction data associated with a candidate model based on applying testing data indicative of current network operating conditions;
calculate a plurality of quality assurance metrics for the candidate model from the received prediction data;
determine a plurality of thresholds based on a plurality of performance distributions derived from a plurality of previously deployed models corresponding to the candidate model, the plurality of performance distributions based on applying the testing data to each of the plurality of previously deployed models;
determine a criteria based on a prediction from a currently deployed model corresponding to the candidate model based on applying the testing data to the currently deployed model; and
automatically deploy the candidate model based on a comparison of the plurality of quality assurance metrics with the plurality of thresholds and a comparison of the plurality of quality assurance metrics with the criteria,
wherein each of the currently deployed model, the candidate model, and the plurality of previously deployed models are configured to predict failure scenarios of a network by detecting anomalous issues occurring on the network from real-time data from network functions.

11. The system of claim 10, wherein the one or more processors are further configured to execute the instructions to:
automatically deploy the candidate model in response to the plurality of quality assurance metrics satisfying the plurality of thresholds and the plurality of quality assurance metrics satisfying the criteria.

12. The system of claim 11, wherein the one or more processors are further configured to execute the instructions to:
generate an alert in response to one or more of: at least one of the plurality of quality assurance metrics failing to satisfy at least one of the plurality the thresholds and at least one of the plurality of quality assurance metrics failing to satisfy the criteria.

13. The system of claim 10, wherein the plurality of quality assurance metrics for the candidate model comprises a value for the candidate model indicative of the prediction data associated with the candidate model and a scale range of the prediction data associated with the candidate model.

14. The system of claim 13, wherein the plurality of thresholds comprises a first threshold based on a first performance distribution of values indicative of prediction data associated with each of the plurality of previously deployed models, and a second threshold based on a second performance distribution of scale ranges of the prediction data associated with each of the plurality of previously deployed models.

15. The system of claim 14, wherein the criteria comprises a scale range of the prediction data associated with the currently deployed model.

16. The system of claim 15, wherein the one or more processors are further configured to execute the instructions to:
determine that the candidate model satisfies a first condition where the value of the candidate model is less than value corresponding to a first percentile of the first performance distribution;
determine that the candidate model satisfies a second condition where the scale range of the candidate model is less than a scale range corresponding to a second percentile of the second performance distribution; and
determine that the candidate model satisfies a third condition where the scale range of the candidate model overlaps with the scale range of the currently deployed model,
wherein the candidate model is automatically deployed responsive to determining the candidate model satisfied the first, second, and third conditions.

17. A non-transitory computer-readable medium comprising computer-readable instructions, the computer-readable instructions when executed by a processor, cause the processor to:
generate a candidate model based on applying a training dataset to a machine-learning algorithm, the training dataset indicative of current network operating conditions of a communication network;
generate a plurality of metrics for the candidate model from network issues detected by the candidate model based on applying a testing dataset to the candidate model;
set a plurality of conditions for the candidate model based on applying the testing dataset to a plurality of previously deployed models, each of the plurality of previously deployed models corresponding to the candidate model; and
determine to deploy the candidate model based the plurality of metrics satisfying the plurality conditions.

18. The system of claim 17, wherein the computer-readable instructions, when executed by the processor, further cause the processor to:
deploy the candidate model onto production run-time machines responsive to a determination that the plurality of metrics satisfies each of the plurality of conditions.

19. The system of claim 17, wherein the computer-readable instructions, when executed by the processor, further cause the processor to:
generate an alert responsive to a determination that the plurality of metrics failed one or more of the plurality of conditions.

20. The system of claim 17, wherein each of the plurality of previously deployed models corresponds to the candidate model based on each of the plurality of previously deployed models being generated from the machine-learning algorithm.
